(19) United States
(12) Patent Application Publication
(10) Pub. No.: US 2013/0082542 A1
(43) Pub. Date: Apr. 4, 2013

(54) ACTUATOR

(71) Applicants: Tetsuo Hino, Yamato-shi (JP); Jun Yamamoto, Tokyo (JP); Canon Kabushiki Kaisha, Tokyo (JP)

(72) Inventors: Tetsuo Hino, Yamato-shi (JP); Jun Yamamoto, Tokyo (JP)

(73) Assignee: CANON KABUSHIKI KAISHA, Tokyo (JP)

(21) Appl. No.: 13/629,439

(22) Filed: Sep. 27, 2012

(30) Foreign Application Priority Data
Oct. 4, 2011 (JP) 2011-220305

(51) Int. Cl. H01G 9/035; H02J 4/00; H01G 9/022; H05K 13/00

(52) U.S. Cl. 307/109; 29/592.1; 361/504; 156/60; 252/62.2

(57) ABSTRACT

An intermediate layer of polyurethane containing an electrolyte in a high concentration can be produced with good productivity and an actuator element having high generative force is provided.

An actuator has a pair of electrode layers and an intermediate layer disposed between the pair of electrode layers and containing an electrolyte and polyurethane, in which the actuator deforms when a voltage is applied between the electrode layers, the content of the electrolyte in the intermediate layer is 60 wt % or more and 300 wt % or lower based on the polyurethane, and the polyurethane is obtained by a reaction of at least a compound represented by General Formula (1) and a compound represented by General Formula (2).

### BACKGROUND OF THE INVENTION

1. Field of the Invention

The present invention relates to an ion migration type actuator.

2. Description of the Related Art

In recent years, an actuator containing an organic polymer as a material has been developed.

Japanese Patent Laid-Open No. 2011-057919 discloses immersing polyurethane resin containing an oxyethylene group in a proportion of 20 to 90 wt % in an ionic liquid for several days to thereby obtain a polyurethane gel film containing the ionic liquid in a proportion of 150 to 300 wt % based on the amount of the polyurethane. The ionic liquid refers to a nonvolatile salt which is present in the form of liquid even at room temperature. Moreover, even when a supporting electrolyte is not added, current can be passed therethrough and also the potential window is wide. Therefore, the ionic liquid has been widely utilized as an electrolyte.

When the polyurethane gel film containing such an ionic liquid in a high concentration is utilized as an ion migration type actuator, good driving properties are obtained due to the high ion content. More specifically, by disposing electrodes in such a manner as to hold the polyurethane gel film to form a three-layer (Electrode/Intermediate layer/Electrode) configuration, for example, it can be expected to utilize the polyurethane gel film for an ion migration type actuator which deforms due to the migration of the ions of the ionic liquid in the polyurethane gel film to the electrode layers with voltage application.

However, a former polyurethane gel film has had the following problems in practical use.

First, it is difficult to obtain a polyurethane gel having a high Young's modulus. In order to sufficiently permeate the ionic liquid into a polyurethane material, a soft polyurethane material is used. Therefore, a film cannot be hardened in some cases. As a result, when applied to an actuator, an improvement of generative force originating from an improvement of mechanical properties of an element is limited.

Second, the productivity is poor. For a method for compounding the ionic liquid, immersion is used, so that a large amount of the ionic liquid based on the immersion amount has been required and several days have been required for immersion.

### SUMMARY OF THE INVENTION

Aspects of the present invention can produce an intermediate layer of polyurethane containing an electrolyte in a high concentration with good productivity and provides an actuator element having high generative force.

An actuator according to aspects of the invention has: a pair of electrode layers; and an intermediate layer disposed between the pair of electrode layers and containing an electrolyte and polyurethane, in which the actuator deforms when a voltage is applied between the electrode layers, the content of the electrolyte in the intermediate layer is 60 wt % or more and 300 wt % or lower based on the polyurethane, and the polyurethane is obtained by a reaction of at least a compound represented by the following General Formula (1) and a compound represented by the following General Formula (2).

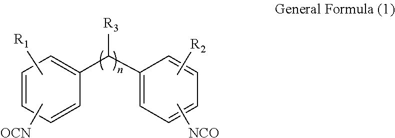

In General Formula (1), R₁, R₂, and R₃ each represent a hydrogen atom or a hydrocarbon group which may have a substituent or a functional group and n is an integer of 1 to 10.

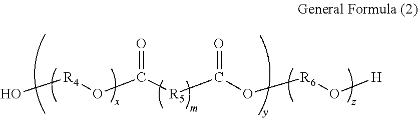

In General Formula (2), R₄, R₅, and R₆ each represent a hydrocarbon group which may have a functional group, m is an integer of 1 to 30, x, y, and z each are 0 or an integer of 1 or more, and R₄ and R₆ may be formed from several kinds of hydrocarbon groups.

According to aspects of the invention, an intermediate layer having a high Young's modulus and containing an ionic liquid in a high concentration can be obtained. As a result, in the application thereof to an actuator, an improvement of generative force originating from an improvement of mechanical properties of an element can be achieved. Moreover, an intermediate layer containing an ionic liquid in a high concentration can be produced with good productivity and an actuator element excellent in practicability is obtained.

Further features of the present invention will become apparent from the following description of exemplary embodiments with reference to the attached drawings.

### BRIEF DESCRIPTION OF THE DRAWINGS

FIG. 1 is a schematic diagram illustrating one embodiment of an actuator according to aspects of the invention.

FIGS. 2A and 2B are schematic views illustrating the migration of ions in an actuator, in which FIG. 2A is a view illustrating a state before voltage application and FIG. 2B is a view illustrating a state after voltage application.

FIGS. 3A to 3D illustrate one example of an embodiment of the invention and are views in which the interaction of diphenylmethane diisocyanate and polyester polyol and an ionic liquid is determined by molecular orbital calculation.

### DESCRIPTION OF THE EMBODIMENTS

Hereinafter, an embodiment of the invention is described.

### Configuration of Actuator

An actuator according to aspects of the invention has: a pair of electrode layers; and an intermediate layer disposed between the pair of electrode layers and containing an electrolyte and polyurethane, in which the actuator deforms when a voltage is applied between the electrode layers, the content of the electrolyte in the intermediate layer is 60 wt % or more and 300 wt % or lower based on the polyurethane, and the polyurethane is obtained by a reaction of at least a compound represented by the following General Formula (1) and a compound represented by the following General Formula (2).

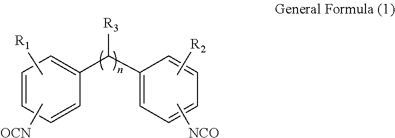

In General Formula (1), R₁, R₂, and R₃ each represent a hydrogen atom or a hydrocarbon group which may have a substituent or a functional group and n is an integer of 1 to 10.

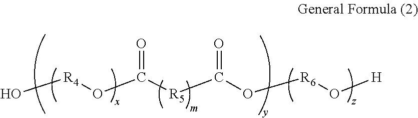

In General Formula (2), R₄, R₅, and R₆ each represent a hydrocarbon group which may have a functional group, m is an integer of 1 to 30, x, y, and z each are 0 or an integer of 1 or more, and R₄ and R₆ may be formed from several kinds of hydrocarbon groups.

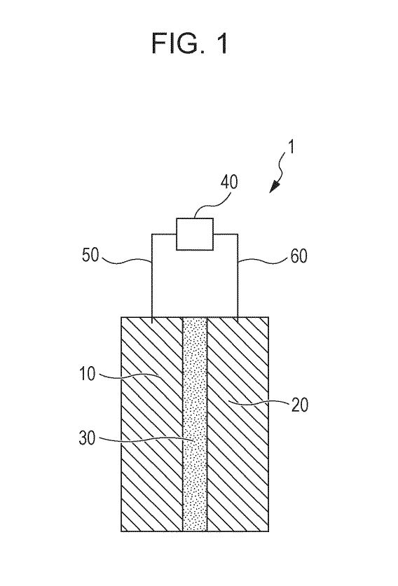

The actuator according to aspects of the invention is described with reference to FIG. 1. FIG. 1 is a schematic diagram illustrating one embodiment of the actuator of the invention.

The actuator of this embodiment is a three-layer laminated actuator containing a first electrode layer 10, a second electrode layer 20, and an intermediate layer 30 which is disposed between the first electrode layer 10 the second electrode layer 20 and contains an electrolyte and polyurethane. Herein, the content of the electrolyte of the intermediate layer is 60 wt % or more and 300 wt % or lower based on the polyurethane. The polyurethane is formed by a reaction of at least a compound (referred to as A) represented by General Formula (1) and a compound (referred to as B) represented by General Formula (2).

The first electrode layer 10 is connected to a drive power supply 40 by a lead wire 50 and the second electrode layer 20 is connected to the drive power supply 40 by a lead wire 60.

Herein, the first electrode layer and the second electrode layer face each other and the intermediate layer 30 contains an ionic liquid as the electrolyte. FIG. 1 illustrates a schematic diagram as viewed when the actuator is seen from a direction perpendicular to the lamination direction (horizontal direction of the paper) of the electrode layers and the intermediate layer.

When a voltage is applied between the first electrode layer and the second electrode layer by the drive power supply, at least cationic species and/or anionic species in the electrolyte move to the electrode layer at the cathode side and/or the electrode layer at the anode side in the intermediate layer. As a result, longer ends (displacement ends) of the actuator bend and deform to either the anode side or the cathode side.

In the ion migration type actuator, the following are expected in the intermediate layer from the viewpoint of practical use. First, since the generative force of the actuator originates from the Young's modulus of the element, the Young's modulus of the intermediate layer is desired to be high. Second, since the migration of electrolyte ions with voltage application is a factor for driving the actuator, it is required to simply produce an intermediate layer holding a larger amount of electrolyte (electrolyte ions) with good productivity.

Then, the present inventors have conducted extensive research, and, as a result, have found that the polyurethane formed by a reaction of at least the compound (A) represented by General Formula (1) and the compound (B) represented by General Formula (2) can provide an intermediate layer containing an electrolyte in a proportion as high as 300 wt % based on the polyurethane in a simple manner. Moreover, it has also been found that the Young's modulus of the obtained intermediate layer film containing the electrolyte is good.

In particular, the ionic liquid containing polyurethane can be produced by one-pot synthesis according to aspects of the invention. More specifically, simply by reacting at least the compound (A) represented by General Formula (1) and the compound (B) represented by General Formula (2) in the presence of the ionic liquid which is the electrolyte, the corresponding ionic liquid containing polyurethane can be easily obtained.

The one-pot synthesis is a process for synthesizing a target compound without performing isolation and refining of an intermediate product during a process of synthesizing the target compound. As a result, the process for producing polyurethane (elastomer) once, and then immersing the polyurethane in an ionic liquid for several days as in Japanese Patent Laid-Open No. 2011-057919 is not required, and the productivity is extremely high.

The mechanism such that the electrolyte can be compounded in a proportion as high as 300 wt % based on the polyurethane by the combination of the compound (A) represented by General Formula (1), and the compound (B) represented by General Formula (2) is not clarified. However, as described below, a result such that the compound (A) and the compound (B) have high interaction with the electrolyte (electrolyte ion) has been obtained by molecular orbital calculation. It is imagined that this is a main factor of the mechanism such that the electrolyte can be compounded in a proportion as high as 300 wt % based on the polyurethane.

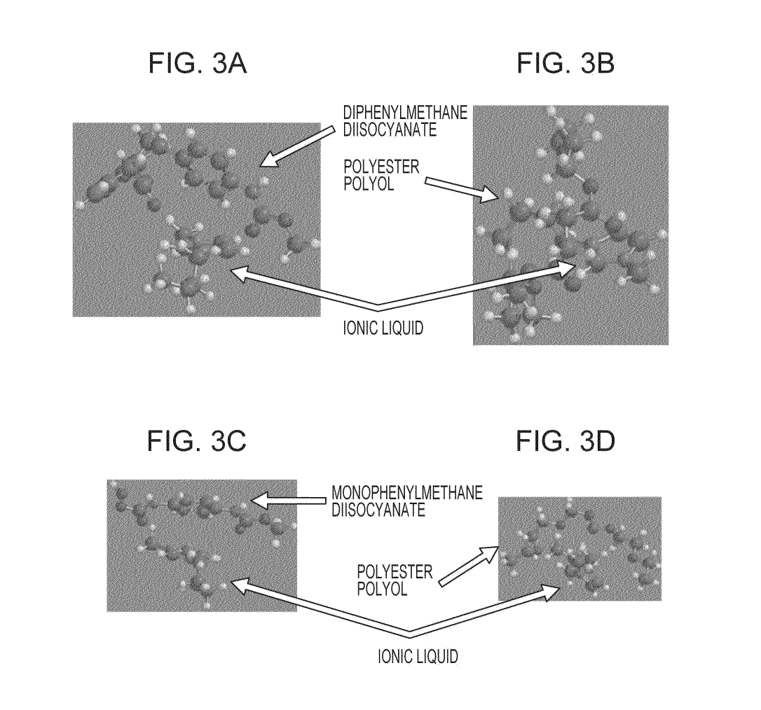

FIGS. 3A to 3D are views illustrating the interaction of diphenylmethane diisocyanate and an ionic liquid and the interaction of polyester polyol and an ionic liquid determined using Spartan'10 for Windows (Registered Trademark) manufactured by Wavefunction by molecular orbital calculation. As the ionic liquid, butyl methyl imidazolium was used as the cationic species.

More specifically, FIG. 3A illustrates the calculation results of the interaction of diphenylmethane diisocyanate(2,4′-Diphenylmethane diisocyanate) and butyl methyl imidazolium which is the cationic species of the electrolyte. FIG. 3A shows that the diisocyanate interacts in such a manner as to connote the ionic liquid. FIG. 3C illustrates similar calculation results using diisocyanate (4,4′-Phenyl diisocyanate) of a monophenyl structure as a comparison. In this case, the connotation observed in FIG. 3A is not observed, and it is suggested that the interaction with the electrolyte (electrolyte ion) is weak.

FIG. 3B illustrates the calculation results of the interaction of a diethoxy ethyl succinate alcohol derivative as a model of polyester polyol and butyl methyl imidazolium which is the cationic species of the electrolytic. Similarly, also in this case, FIG. 3B shows that the diethoxy ethyl succinate alcohol derivative interacts in such a manner as to connote the ionic liquid. In contrast, FIG. 3D illustrates similar calculation results using the corresponding polyether polyol not having a ketone part of the diethoxy ethyl succinate alcohol derivative as a comparison. In this case, the connotation observed in FIG. 3B is not observed, and it is suggested that the interaction with the electrolyte (electrolyte ion) is weak. Even when the type of the ionic liquid is changed, it is concluded that the same calculation results are obtained.

In the actuator according to aspects of the invention, the compound (A) represented by General Formula (1) and the compound (B) represented by General Formula (2) which have good interaction with an electrolyte are produced in the presence of the electrolyte by one-pot. More specifically, since there is no necessity of swelling it later, and then compounding an electrolyte therein, the structure of the polyurethane skeleton itself is not required to be soft. Thus, polyurethane containing an electrolyte in a high concentration and having a relatively strong polymer network can be easily designed and produced. As a result, polyurethane is obtained which contributes to an improvement of generative force of an actuator, has high film strength, and contains an electrolyte in a high concentration.

More specifically, the present inventors have found an electrolyte containing structure which contains an electrolyte and polyurethane obtained by a reaction of the compound represented by General Formula (1) and the compound represented by General Formula (2) and in which the content of the electrolyte is 60 wt % or more and 300 wt % or lower based on the polyurethane, and further have found that a suitable actuator is obtained by the use of the electrolyte containing structure as an intermediate layer of an actuator.

The polyurethane exhibits adhesiveness depending on the combination of monomers and the degree of polymerization, and also in the polyurethane to be obtained according to aspects of the invention containing an electrolyte in a high concentration also has adhesiveness. As a result, an element can be simply produced merely by pressure-bonding the polyurethane at room temperature in a lamination process with electrodes. Also from this viewpoint, it is suitable to apply the intermediate layer to be obtained according to aspects of the invention to an actuator.

Hereinafter, the configuration of the actuator according to aspects of the invention is specifically described.

### Electrode Layer

The first electrode layer and the second electrode layer according to aspects of the invention are not particularly limited. An electrode layer having flexibility known as an electrode layer of an actuator (soft actuator) containing an organic polymer as a material can be used as appropriate. Specifically, a flexible electrode layer containing at least a conductive polymer, one obtained by pressing and hardening a conductive material, such as or CNT, or a conductive material, such as CNT, and a polymer is mentioned.

The electrode layer may be constituted by a film-like film formed by a cast method or the like and containing a conductive material, an electrolyte, and a polymer.

For example, the electrode layer may be a gel electrode layer formed from a carbon nanotube and an ionic liquid or a flexible electrode layer containing a binder polymer in addition thereto. Or, the electrode layer may be a film formed from a carbon nanotube and various polymer electrolytes. It is a matter of course that the electrode layer may be a film formed from at least a conductive polymer as described in Japanese Patent Laid-Open No. 2011-057919.

As the shape of the electrode layer, an electrode layer of a square shape, an oval shape, or the like can be used. In the case an actuator having a long shape, a long shape in which the length in the direction from one end to the other end is longer as described above is suitable because a large displacement amount can be obtained when the actuator bends and deforms. The first and second electrode layers may be electrode layers having the same configuration or formed with different materials and different shapes.

As the conductive material of the electrode layer, carbon-based conductive substances can be compounded singly or as a mixture thereof. In general, as the carbon-based conductive substances, black lead, carbon black, acetylene black, Ketjenblack, an activated carbon fiber, nanocarbon materials (carbon whisker (Vapor-grown carbon), (nano)carbon fibers, carbon nanoparticles, graphene, and a carbon nanotubes), and a conductive polymer can also be used. Among the above, the nanocarbon materials are suitable from the viewpoint of conductivity and a specific surface area, and CNT is particularly suitable.

The CNT which is one of the nanocarbon materials is obtained by rolling graphene into a cylinder, and the diameter of the cylinder is 1 to 10 nm. The carbon nanotube for use in the actuator according to aspects of the invention is a carbon-based material having a shape in which a graphene sheet is rolled into a cylinder and is roughly classified into a single layer nanotube (SWCNT) and a multilayer nanotube (MWCNT) from the number of circumferential walls. Various carbon nanotubes are known. In the actuator according to aspects of the invention, any kinds of carbon nanotube can be used insofar as it is referred to as a so-called carbon nanotube.

The carbon nanoparticle which is one of the nanocarbon materials for use in the actuator according to aspects of the invention refers to a nanoscale (10⁻⁶ to 10⁻⁹ m) particle containing carbon as the main ingredients, such as carbon nanohorn, amorphous carbon, and fullerene other than the carbon nanotube. The carbon nanohorn refers to a carbon nanoparticle having a shape such that a graphite sheet is rolled into a cone and the tip is closed in the shape of a cone.

The nanocarbon fiber which is one of the nanocarbon materials for use in the actuator according to aspects of the invention is obtained by rolling a graphite sheet into a cylinder, the diameter of the cylinder is 10 to 1000 nm, and the nanocarbon fiber is also referred to as a carbon nanofiber. The carbon nanofiber is a carbon-based fiber having a fiber thickness of 75 nm or more, having a hollow structure, and having a large number of branched structures. As a commercially available item, VGCF and VGNF of Showa Denko K.K. are mentioned.

The graphene which is one of the nanocarbon materials for use in the actuator according to aspects of the invention is a part of a black lead structure and is an assembly of carbon atoms in which carbon 6-membered rings having a planar structure are two-dimensionally arranged, i.e., one having one carbon layer.

The addition amount of the conductive material in the electrode layer of the actuator according to aspects of the invention is suitably 1 wt % or more based on the weight of the electrode layer. Due to the fact that the addition amount of the conductive material is 1 wt % or more based on the weight of the electrode layer, the electrical conductivity which allows the electrode layer to function as an electrode layer of an actuator can be imparted. Thus, the addition amount is suitable. When the content is lower than 1 wt %, the conductivity of the electrode layer cannot be sufficiently obtained in some cases, and the content is not suitable.

When the polymer constituting the electrode layer is not particularly limited insofar as it has flexibility which allows the electrode layer to deform with the deformation of the actuator. The polymer suitably has less hydrolysis properties and is stable in the atmosphere. As such a polymer, polyolefin polymers, such as polyethylene and polypropylene; polystyrene; polyimide; polyarylenes (aromatic polymers), such as polyparaphenylene oxide, poly(2,6-dimethylphenylene oxide), and polyparaphenylene sulfide; polymers in which a sulfonate group (—SO₃H), a carboxyl group (—COOH), a phosphate group, a sulfonium group, an ammonium group, or a pyridinium group is introduced into a polyolefin polymer, polystyrene, polyimide, or polyarylenes (aromatic polymers); fluorine-containing polymers, such as polytetrafluoroethylene and polyvinylidene fluoride; perfluorosulfonic acid polymers, perfluorocarboxylic acid polymers, and perfluorophosphoric acid polymers, in which a sulfonate group, a carboxyl group, a phosphate group, a sulfonium group, an ammonium group, or a pyridinium group is introduced into the skeleton of a fluorine-containing polymer; polybutadiene compounds; polyurethane compounds, such as elastomer and gel; silicone compounds; polyvinyl chloride; polyethylene terephthalate; nylon; and polyarylate can be mentioned. These substances may be used singly or in combination of two or more kinds thereof, may be functionalized, or may form a copolymer with other polymers.

Suitable as the polymer are a fluororesin material, e.g., a polyvinylidene fluoride-hexafluoro propylene copolymer (PVDF-HFP), a polyvinylidene fluoride (PVDF), and the like are suitable from the viewpoint of the chemical stability of materials. Moreover, the polymer is suitably a polymer having high compatibility with the intermediate layer. Thus, since the compatibility and the bondability with the intermediate layer are higher, electrode layers which are more firmly laminated and bonded can be constituted. To that end, the polymer may be a polymer having a polymeric structure or a functional group of the same type as, similar to, or identical to that of a polyanion polymer material constituting the intermediate layer.

As described above, the electrode layer in the actuator according to aspects of the invention is imparted with conductivity due to the fact that a polymer and the conductive material dispersed therein are contained. The electrical resistance value of the electrode layer is 1000 Ω·cm or lower and suitably 100 Ω·cm or lower. The Young's modulus is suitably 0.1 to 600 MPa. When the Young's modulus is in this range, the flexibility and the elasticity of the electrode layer are improved and the plastic deformation resistance is improved in the application to an actuator. Therefore, an ion migration type actuator having high repetition durability can be produced.

The electrode layer may contain an ingredient other than the polymer and the conductive materials mentioned above, e.g., a weak acidic substance in aspects of the invention, insofar as it does not exert adverse effects on the function of the actuator. The amount of the ingredient other than the polymer and the conductive material to be compounded is particularly suitably 10 wt % or more and 60 wt % or lower. For example, it is suitable from the viewpoint of conductivity that the ratio of the conductive material to the polymer amount is higher. When the polymer amount is lower than 1 wt %, the electrode layer has no self-supporting properties and is mechanically weak in some cases. When the polymer amount exceeds 80 wt %, the amount of the conductive substance to be compounded relatively becomes small, so that the conductivity for functioning as an electrode layer may be insufficient in many cases, which sometimes results in the fact that the electrode layer is difficult to practically use in terms of the response rate, the deformation response properties, and the like of an actuator.

The thickness of the electrode layer is not particularly limited insofar as the deformation of the actuator is not hindered and is 1 μm or more and 5 mm or lower, suitably 5 μm or more and 2 mm or lower, and still more suitably 10 μm or more and 500 μm or lower. When the thickness of each electrode layer is lower than 1 μm, the electrode layer poses a problem of electrical conductivity as an electrode layer of an actuator. Thus, the thickness is not suitable. When the thickness of the electrode layer is larger than 5 mm, the electrode layer becomes hard and is easily cracked because the electrode layer contains conductive materials. Thus, the thickness is not suitable. The thickness and the material of the electrode layer at the negative electrode side and the electrode layer at the positive electrode side do not need to be the same and can be selected as appropriate according to predetermined actuator properties.

### Intermediate Layer

### Method for Producing Intermediate Layer

For the intermediate layer, a known polyurethane can be used as appropriate insofar as the polyurethane is polyurethane formed by a reaction of at least the compound (A) represented by General Formula (1) and the compound (B) represented by General Formula (2) in the presence of an electrolyte and is obtained by one-pot polymerization in such a manner that the content of the electrolyte of the intermediate layer is 60 wt % or more and 300 wt % or lower based on the polyurethane. For example, a melt polymerization method or a mass polymerization method is suitable, and particularly when the compound (A) and the compound (B) are liquid, a mass polymerization method is more suitable from the viewpoint of taking measures against VOC. More specifically, when the compound (A) and compound (B) described above are liquid, for example, polyurethane having a uniform film thickness and containing a given amount of the electrolyte according to aspects of the invention can be easily obtained by sufficiently stirring the compound (A) and compound (B) in the presence of a given amount of ionic liquid, pouring the mixture into a die produced with Teflon (Registered Trademark) or the like, and then heating.

The ratio of the compound (A) and the compound (B) can be determined as appropriate according to a predetermined Young's modulus of the intermediate layer. It is a matter of course that a known crosslinking agent and a known chain extender may optionally be added.

The compound (A) can be selected from known diisocyanate compounds according to the intended use or the required performance. For example, 2,4-tolylene diisocyanate, 2,6-tolylene diisocyanate, 4,4′-diphenylmethane diisocyanate, xylylene diisocyanate, a denatured substance thereof, and the like can be mentioned. As a commercially available item, MC-115 manufactured by NIPPON POLYURETHANE INDUSTRY CO., LTD. and the like are mentioned.

The compound (B) can be selected from known polyester polyol compounds according to the intended use or the required performance. Mentioned as the polyester polyol as the compound (B) are, for example, polyethylene adipate diol, polybutylene adipate diol, polyhexamethylene adipate diol, polyhexamethylene isophthalate diol, polyneopentyl adipate diol, polyethylene propylene adipate diol, polyethylene butylene adipate diol, polybutylene hexamethylene adipate diol, polydiethylene adipate diol, poly(polytetramethyleneether)adipate diol, poly(3-methylpentylene adipate)diol, polyethylene azelate diol, polyethylene sebacate diol, polybutylene azelate diol, polybutylene sebacate diol, polyneopentyl terephthalate diol, and the like. As a commercially available item, Nippollan 4042 manufactured by NIPPON POLYURETHANE INDUSTRY CO., LTD. and the like can be mentioned.

The polyester polyol as the compound (B) can also be obtained by a reaction (condensation) of polyol (derivative) having a number average molecular weight (Mn) of lower than 400 and polyvalent carboxylic acid or an ester formable derivative thereof.

Mentioned as the polyvalent carboxylic acid or the ester formable derivative thereof are aliphatic dicarboxylic acids (succinic acid, adipic acid, azelaic acid, sebacic acid, fumaric acid, maleic acid, and the like), anhydrides thereof (succinic anhydride, maleic anhydride, phthalic anhydride, trimellitic anhydride, and the like), acid halides thereof (adipic acid dichloride and the like), low molecular weight alkyl esters thereof (dimethyl succinate, dimethyl phthalate, and the like), and a combination thereof.

Mentioned as the polyol (derivative) having a number average molecular weight (Mn) of lower than 400 Mn are, for example, polyether polyols, such as polyethylene glycol, polypropylene glycol, polytetramethylene glycol and poly(methyl tetramethylene glycol) and copolymers thereof; polyester polyols, such as polybutylene adipate diol, polybutylene sebacate diol, polyhexamethylene adipate diol, poly(3-methyl-1,5-penthylene adipate)diol, poly(3-methyl-1,5-penthylene sebacate)diol, and polycaprolactone diol and copolymers thereof; polycarbonate polyols, such as polyhexamethylene carbonate diol, poly(3-methyl-1,5-penthylene carbonate)diol, polypentamethylene carbonate diol, and polytetramethylene carbonate diol and copolymers thereof; polyester carbonate polyol, and the like, and one or two or more of these substances can be used.

The intermediate layer in aspects of the invention is a polyurethane material containing a given amount of an electrolyte and is not particularly limited insofar as it is a polymer containing an ionic liquid as an electrolyte in many cases. Although it is needless to say, the intermediate layer may contain a plurality of electrolyte substances. Furthermore, it is a matter of course that a plurality of the compounds (A) and the compounds (B) which are constituent materials of polyurethane may be used.

As the shape of the intermediate layer, an arbitrary shape can be used. When the intermediate layer has a long shape, a large displacement amount can be obtained when the actuator is driven to deform. Thus, the long shape is suitable.

The intermediate layer can be used as a deformation portion of an ion migration type actuator which contains a given amount of an electrolyte and deforms by voltage application.

When the amount of the electrolyte is 60 wt % or more and 300 wt % or lower based on polyurethane, the ion conductivity and the film mechanical properties are good. When utilized as an actuator element, good driving properties are exhibited. In contrast, when the amount of the electrolyte is lower than 60 wt %, the ion conductivity is low. When the amount of the electrolyte is larger than 300 wt %, the film mechanical properties tend to be low.

As the electrolyte, lithium fluoride, lithium bromide, sodium bromide, magnesium chloride, copper sulfate, sodium acetate, sodium oleate, sodium acetate, and the like can be mentioned, for example. It is a matter of course that the electrolyte may be an ionic liquid.

The ionic liquid for use in the actuator according to the embodiment of the invention is also referred to as a room temperature molten salt or simply referred to as a molten salt. The ionic liquid is a salt which exhibits a molten state in a wide temperature region including normal temperature (room temperature) and is a salt which exhibits a molten state at 0° C., suitably −20° C., and still more suitably −40° C., for example. The ionic liquid is suitably one having high ion conductivity. As compared with a common organic solvent or aqueous liquid electrolyte, there is a tendency that the ionic liquid is excellent in fire retardancy, low volatility, thermal stability, and further electrochemical stability as an electrolyte.

In the actuator according to the embodiment of the invention, known various kinds of ionic liquids can be used and the ionic liquid is not particularly limited. The ionic liquid is suitably a stable one which exhibits a liquid state at normal temperature (room temperature) or a temperature near normal temperature. Mentioned as a suitable ionic liquid for use in the actuator according to the embodiment of the invention are imidazolium salt, pyridinium salt, ammonium salt, phosphonium salt, and the like. Two or more of the ionic liquids mentioned above may be combined for use.

More specifically, as the ionic liquid, one containing cations (suitably, imidazolium ion) represented by the following General Formulae (1) to (4) and anions (X⁻) can be mentioned as an example.

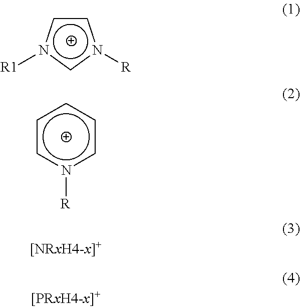

In the Formulae (1) to (4) above, R represents an alkyl group having 1 to 12 carbon atoms or an alkyl group containing an ether bond and carbon and oxygen of 3 to 12 in total. In Formula (1), R₁ represents an alkyl group having 1 to 4 carbon atoms or a hydrogen atom. In Formula (1), R and R₁ are suitably not the same. In Formulae (3) and (4), x is an integer of 1 to 4.

The anion (X⁻) is suitably at least one selected from tetrafluoroborate anion, hexafluorophosphate anion, bis(trifluoromethanesulfonyl)imidate anion, perchlorate anion, tris(trifluoromethanesulfonyl)carbonate anion, trifluoromethanesulfonate anion, dicyanamide anion, trifluoroacetate anion, organic carboxylate anion, and halogen ion.

The thickness of the electrolyte layer is suitably 10 μm or more and 500 μm or lower and more suitably 10 μm or more and 400 μm or lower. When the film thickness is larger than 500 μm, the elastic modulus of the film increases, so that the deformation movement of an actuator is suppressed in some cases. When the film thickness is lower than 10 μm, the amount of ionic substances that can be held is small and the supply amount to an electrode layer decreases, so that bending movement is not sufficiently obtained in some cases.

### Drive Mechanism of Ion Migration Type Actuator

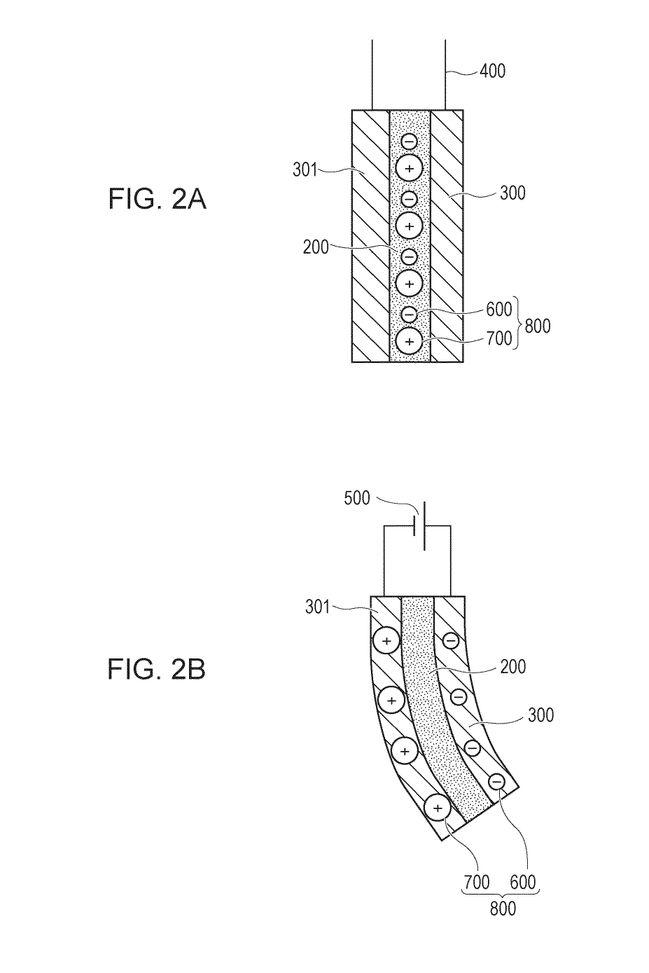

The drive principle when the actuator according to aspects of the invention bends and deforms is described with reference to FIGS. 2A and 2B.

As illustrated in FIG. 2A, two electrode layers 300 and 301 are formed on the surface of an intermediate layer 200 in a state where the electrode layers are insulated from each other. When a potential difference is applied between the electrode layers 300 and 301, with respect to positive ions 700 and negative ions 600 of an electrolyte 800, the positive ions 700 move and permeate into the electrode layer 301 which is a cathode and the negative ions 600 move and permeate into the electrode layer 300 which is an anode as illustrated in FIG. 2B. An electric double layer is formed on the interface of a conductive material and an ionic substance phase in the electrode layers 300 and 301. An ionic liquid without steam pressure is suitable as the electrolyte according to aspects of the invention from the viewpoint of the drive in the atmosphere. In the ionic liquid, the ion radius of the positive ion 700 is larger than that of the negative ion 600. As a result, it is considered that the steric effect of the ions present in the electrode layer and the electrostatic repulsion with the formation of the electric double layer cooperatively act, so that the electrode layer 301 further expands as compared with the electrode layer 300 and the actuator bends in a direction where the cathode further extends as compared with the anode. In usual, when the polarity of the potential is reversed, the film bends and deforms in an opposite direction. The displacement direction changes depending on the configuration of the electrode layers or the intermediate layer.

Moreover, it is considered that also when either one of the positive ion or the negative ion is fixed to the intermediate layer and only the other ion moves, the film bends and deforms based on the same principle. In this case, the film bends and deforms not due to a difference in expansion of the two electrode layers but due to expansion of one electrode.

Herein, the intermediate layer according to aspects of the invention is polyurethane in which a high-concentration electrolyte is compounded and the ion conductivity and the film mechanical properties are good, and, as a result, an actuator having high generative force is obtained.

The applied voltage in the actuator according to the embodiment of the invention can be determined within the withstand voltage of the electrolyte.

### Manufacturing of Actuator

### Method for Manufacturing Actuator

A method for manufacturing the actuator according to the embodiment of the invention has a process for forming the intermediate layer described above. More specifically, the method has a process for one-pot synthesizing polyurethane containing an electrolyte in a proportion of 60 wt % or more and 300 wt % or lower based on the polyurethane from at least the compound represented by the following General Formula (1) and the compound represented by the following General Formula (2) in the presence of the electrolyte.

Thereafter, an actuator illustrated in FIG. 1 can be manufactured by laminating the formed intermediate layer and a pair of electrode layers.

A method for laminating the electrode layers and the intermediate layer, followed by pressing (including thermal press, hot press, and thermocompression bonding) can be suitably used. Herein, since the intermediate layer has adhesiveness as described above, a laminate can be easily obtained at room temperature even when “thermal press” is not performed.

The temperature, press pressure, and time of the thermal press are not particularly limited insofar as a temperature equal to or lower than the decomposition temperature of the electrolyte and the polyurethane is achieved and may be selected as appropriate according to a polymer to be used, a polymer compound constituting the actuator, the species of the moving ion, and the like. For example, the temperature of the thermal press is suitably 30 to 150° C. The press pressure is suitably 10 to 1000 (1 to 100 kgf/cm²) and more suitably 100 to 500 Pa (10 to 50 kgf/cm²).

The shape of the actuator according to the embodiment of the invention is not limited to the above-described lamination shape, and an element of an arbitrary shape, such as a columnar shape in which a central axis and a peripheral electrode layer are provided and an intermediate layer is provided therebetween, can be easily manufactured.

Although the actuator may be used singly, a plurality of the actuators may be accumulated to be constituted as a driving device in which the force generated from each actuator is combined.

Hereinafter, the embodiment of the invention is described.

### Performance Evaluation of Actuator

An actuator is produced in a rectangular shape with a width of 1 mm, a length of 12 mm, and a predetermined film thickness, a 2 mm portion at the end is held with a holder (terminal) with a platinum electrode of a fixing instrument, and then a voltage is applied in the air (drive in the air). With respect to the deformation response properties of the actuator, the displacement amount at a predetermined position is evaluated. With respect to the displacement amount, the displacement at a drive voltage of +1.0 to 7.0 V and a drive frequency of 0.1 Hz is measured at a position (actuator measurement point) 9 mm from the fixed end using a laser displacement meter. The Young's modulus was measured using a tensile tester (manufactured by Shimazu).

### Example 1

### Production of Intermediate Layer

The polyurethane intermediate layer containing an electrolyte in a high concentration was produced in the following processes.

As an electrolyte, 1-ethyl-3-methyl imidazolium bis(trifluoromethanesulfonyl)imide (EMITFSI manufactured by Tokyo Chemical Industry Co., Ltd.) was used. As the compound (A), MC-115 (manufactured by NIPPON POLYURETHANE INDUSTRY CO., LTD.) was used. As the compound (B), Nippollan 4042 (manufactured by NIPPON POLYURETHANE INDUSTRY CO., LTD.) was used. More specifically, EMITFSI, MC-115, and Nippollan 4042 were mixed with a given compounding ratio shown in Table 1, the mixed solution was applied to a Teflon (Registered Trademark) mold using a bar coater, and then the mold was heated at 120° C., thereby obtaining the corresponding polyurethane containing the electrolyte in a high concentration (Table 1).

TABLE 1

| | CONTENT OF | COMPOUNDING RATIO | | | |
|---|---|---|---|---|---|
| | IONIC LIQUID TO | α = [OH GROUP EQUIVALENT | OOZING | ELECTRICAL | YOUNG'S |
| | POLYURETHANE | WEIGHT]/[NCO EQUIVALENT | OF IONIC | RESISTIVITY | MODULUS |
| Run | ELASTOMER (%) | WEIGHT] | LIQUID | (Ω × 10³) | (Mpa) |
| 1 | 50 | 1.3 | X | 48 | 14 |
| 2 | 100 | 1.3 | X | 5.8 | 14 |
| 3 | 150 | 1.3 | X | 1 | 15 |
| 4 | 200 | 1.3 | X | 0.9 | 14 |
| 5 | 150 | 1.05 | X | 1.3 | 51 |
| 6 | 200 | 1.05 | X | 1 | 51 |
| 7 | 300 | 1.05 | X | 0.9 | 51 |
| 8 | 400 | 1.05 | ◯ | — | — |

As a result, all the corresponding electrolyte containing polyurethane films in Table 1 were easily produced by one-pot synthesis. The film in which oozing of the ionic liquid did not occur was marked by x and the film in which oozing of the ionic liquid occurred was marked by ◯. The oozing of the ionic liquid was judged by producing an intermediate layer, putting a nonwoven fabric to the intermediate layer, and then visually observing whether the nonwoven fabric got wet. In the configuration according to aspects of the invention, it can be confirmed that the electrolyte (ionic liquid) can be stably compounded in a proportion as high as 300 wt % based on polyurethane.

It was also confirmed that when the electrolyte (ionic liquid) was 60 wt % or lower (50 wt %), the electrical resistance of the film was high and, in contrast, when the electrolyte (ionic liquid) was 300 wt % or more (400 wt %), the ionic liquid oozed, so that the film was softened.

In addition, it was also confirmed that the Young's modulus of the obtained film can be controlled by changing the compounding ratio of the compound (A) and the compound (B).

### Comparative Example 1

As a comparative example, the production of a corresponding ionic liquid containing polyurethane film was attempted by similarly performing one-pot synthesis in the presence of a predetermined amount of EMITFSI using monophenyl diisocyanate and polyether polyol manufactured by EXSEAL Co., Ltd. which do not correspond to the compound (A) and the compound (B).

However, in this comparative example, when the content of the electrolyte (ionic liquid) was 50 wt % or more, the ionic liquid oozed, so that an intermediate layer for an actuator was not stably obtained.

The results obtained above show that, by the one-pot reaction of the compound (A) represented by General Formula (1) and the compound (B) represented by General Formula (2) in the presence of the electrolyte, the electrolyte compounded in the intermediate layer is 60 wt % or more and 300% or lower based on the polyurethane and the polyurethane can be easily obtained, and it is suggested that the polyurethane is promising for application to an actuator.

Next, the utilization to an actuator was examined.

### Example 2

This example 2 is an actuator of a three-layer structure in which a pair of electrode layers and an intermediate layer containing polymer fibers are laminated as illustrated in FIG. 1.

The electrode layers were produced in the following processes.

First, 50 mg of a single layer carbon nanotube (SWNT manufactured by Unidym, Trade name “HiPco”) having a diameter of about 1 nm and a length of 1 μm, 100 mg of an ionic liquid (EMITFSI manufactured by Tokyo Chemical Industry Co., Ltd.), and 1 mL of an organic solvent, N,N-dimethyl acetamide (DMAc manufactured by Kishida Chemical Co., Ltd.) were placed in a container.

Zirconia balls having a particle diameter of 2 mm were added to reach ⅓ of the container capacity, and then dispersion treatment was performed under the conditions of 200 rpm/30 minutes using a ball mill machine (Planetary ball mill manufactured by Fritsch).

Subsequently, a solution produced by heating and dissolving 80 mg of PVdF-HFP (manufactured by Sigma-Aldrich) which is a base material with DMAc (2 mL) was added, and then dispersion treatment was further performed under the conditions of 500 rpm/60 minutes.

A black paste in which the obtained CNT was dispersed was poured into a mold containing PTFE, evenly smoothened with a blade or the like, and then vacuum-dried at room temperature, thereby obtaining an electrode layer in which conductive materials were uniformly dispersed and which had a uniform thickness. The obtained electrode layer was cut into a predetermined size (1 mm×12 mm) for use. The thickness was 50 μm. The electrical conductivity of the film was approximately 13 S/cm.

As the polyurethane intermediate layer containing an electrolyte in a high concentration, the polyurethane obtained using 150 wt % of an ionic liquid based on polyurethane, which was produced in Run 5 of Example 1, was cut into a predetermined size (1.5 mm×14 mm) for use. The film thickness was 100 μm.

By pressure bonding the electrode layers on and under the electrolyte layer at room temperature, an actuator element of a three-layer configuration of Electrode layer/Intermediate layer/Electrode layer was produced.

Thereafter, the intermediate layer sticking out of the actuator element was cut to produce an actuator element for measurement (The width is 1 mm, the length is 120 mm, and the thickness is 200 μm.).

The results of the displacement properties when voltages of 0.1 Hz and +1 V to +7 V were applied are shown in Table 2.

TABLE 2

| APPLIED VOLTAGE | DISPLACEMENT AMOUNT |
|---|---|
| (V) | (mm) |
| +1 | 0.15 |
| +2 | 0.22 |
| +3 | 0.43 |
| +4 | 0.65 |
| +5 | 0.98 |
| +6 | 1.20 |
| +7 | 1.38 |

As shown in Table 2, it was confirmed that an actuator which can be stably driven is obtained by utilizing the electrolyte containing polyurethane in aspects of the invention as an intermediate layer.

It was also confirmed that the displacement amount increases by increasing a voltage, and the actuator can be stably driven at up to about several volts.

### Comparative Example 2

As an intermediate layer of an ion migration type actuator, an intermediate layer produced by mixing PVDF-HFP which is a fluorine-based polymer and an ionic liquid was produced with reference to Japanese Patent Laid-Open No. 2005-176428. When an actuator was produced using the intermediate layer in the same manner as in Example 1, and then the Young's modulus was determined. Then, the Young's modulus was about 0.2 to 0.6 Mpa.

As a result, it was confirmed that the Young's modulus of the intermediate layer of this example was remarkably high as compared with that of Comparative Example 2, and an actuator having high generative force is obtained.

Specific examples of the invention are described above in detail. However, the specific examples are simply examples and do not limit the claims of the invention. The technique described in the claims of the invention may include modifications and alterations of the above-described specific examples.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-220305 filed Oct. 4, 2011, which is hereby incorporated by reference herein in its entirety.

What is claimed is:

1. An actuator, comprising:
a pair of electrode layers; and
an intermediate layer disposed between the pair of electrode layers and containing an electrolyte and polyurethane, wherein the actuator deforms when a voltage is applied between the electrode layers,
the content of the electrolyte in the intermediate layer is 60 wt % or more and 300 wt % or lower based on the polyurethane, and
the polyurethane is obtained by a reaction of at least a compound represented by the following General Formula (1) and a compound represented by the following General Formula (2), 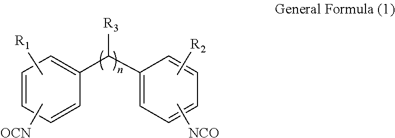
in General Formula (1), R₁, R₂, and R₃ each represent a hydrogen atom or a hydrocarbon group which may have a substituent or a functional group and n is an integer of 1 to 10; and 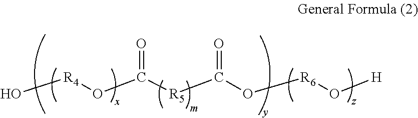
in General Formula (2), R₄, R₅, and R₆ each represent a hydrocarbon group which may have a functional group, m is an integer of 1 to 30, x, y, and z each are 0 or an integer of 1 or more, and R₄ and R₆ may be formed from several kinds of hydrocarbon groups.

2. The actuator according to claim 1, wherein the electrolyte is an ionic liquid.

3. The actuator according to claim 1, wherein the electrode layer contains a nanocarbon material.

4. A driving device, which is formed by accumulating a plurality of the actuators according to claim 1.

5. A method for manufacturing an actuator having a pair of electrode layers and an intermediate layer disposed between the pair of electrode layers and containing an electrolyte and polyurethane, the actuator deforming when a voltage is applied between the electrode layers,
the method comprising:
one-pot synthesizing polyurethane containing an electrolyte in a proportion of 60 wt % or more and 300 wt % or lower based on the polyurethane from at least a compound represented by the following General Formula (1) and a compound represented by the following General Formula (2) in the presence of the electrolyte, 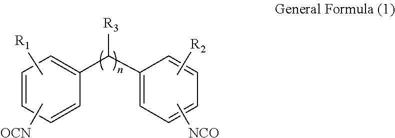
wherein, in General Formula (1), R₁, R₂, and R₃ each represent a hydrogen atom or a hydrocarbon group which may have a substituent or a functional group and n is an integer of 1 to 10; and 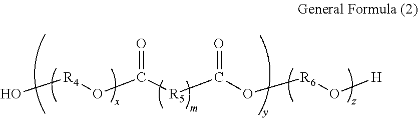
in General Formula (2), R₄, R₅, and R₆ each represent a hydrocarbon group which may have a functional group, m is an integer of 1 to 30, x, y, and z each are 0 or an integer of 1 or more, and R₄ and R₆ may be formed from several kinds of hydrocarbon groups.

6. The method for manufacturing an actuator according to claim 4, further comprising:
laminating and pressing the intermediate layer obtained by the one-pot synthesis and the pair of electrode layers.

7. An electrolyte containing structure, comprising:
an electrolyte; and
polyurethane obtained by a reaction of a compound represented by the following General Formula (1) and a compound represented by the following General Formula (2),
wherein the content of the electrolyte is 60 wt % or more and 300 wt % or lower based on the polyurethane, 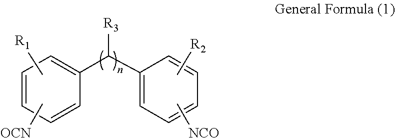
in General Formula (1), R₁, R₂, and R₃ each represent a hydrogen atom or a hydrocarbon group which may have a substituent or a functional group and n is an integer of 1 to 10; and 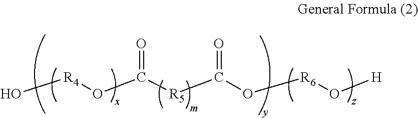
in General Formula (2), R₄, R₅, and R₆ each represent a hydrocarbon group which may have a functional group, m is an integer of 1 to 30, x, y, and z each are 0 or an integer of 1 or more, and R₄ and R₆ may be formed from several kinds of hydrocarbon groups.
